(19) United States
(12) Patent Application Publication
(10) Pub. No.: US 2024/0287381 A1
(43) Pub. Date: Aug. 29, 2024

(54) LIGHT-EMITTING AND PROTECTED NANOPARTICLE, A MANUFACTURING METHOD THEREOF AND AN APPLICATION THEREOF FOR THE OPTOELECTRONIC DEVICE RADIATION CONVERTERS

(71) Applicant: ALEDIA, ÉCHIROLLES (FR)

(72) Inventors: Eleonora GARONI, SEYSSINET-PARISET (FR); Christophe LINCHENEAU, Moirans (FR)

(21) Appl. No.: 18/573,268

(22) PCT Filed: Jun. 30, 2022
(86) PCT No.: PCT/FR2022/051307

§ 371 Date: Dec. 21, 2023

(30) Foreign Application Priority Data
Jun. 30, 2021 (FR) FR2107021

(51) Int. Cl. C09K 11/02; B82Y 20/00; B82Y 40/00; C08K 9/04; C09K 11/08; C09K 11/88; C23C 16/40; C23C 16/44; C23C 16/455; H01L 33/50

(52) U.S. Cl. CPC C09K 11/025; C08K 9/04; C09K 11/0883; C09K 11/883; C23C 16/403; C23C 16/405; C23C 16/4417; C23C 16/45525; H01L 33/502; B82Y 20/00; B82Y 40/00; C08K 2201/011

(57) ABSTRACT

The invention relates to a protected and light-emitting nanoparticle (5a) which is composed of a light-emitting nanoparticle (8a) in the form of a light-emitting core (1), said core (1) being coated with at least one oxidation protection layer (3), said nanoparticle (5a) further comprising a layer (4) formed of second ligands (6) which are grafted to the surface of said oxidation protection layer (3). The invention also relates to a method for producing this nanoparticle (5a) and the use thereof for optoelectronic device radiation converters.

### TECHNICAL FIELD

The disclosure concerns the protection against the external agents (water, oxygen and free radicals resulting from polymerization reactions of photo- and heat-sensitive resins) of light-emitting nanoparticles, in particular quantum dots, which are used in the optoelectronic devices (for example the display screens and the image projection systems).

By “optoelectronic device” is meant in the context of the present disclosure a device suitable for performing the conversion of an electrical signal into electromagnetic radiation to be emitted (in particular light).

### BACKGROUND

There are optoelectronic devices including a matrix of light-emitting diodes (hereinafter referred to as “LED”) having an emission surface through which the light radiation emitted by the LEDs is transmitted. Such optoelectronic devices are used in the constitution of display screens or image projection systems, in which the matrix of LEDs defines a matrix of “image elements” (also called “pixels”) which emit each light, so that the image on the screen may be controlled by individually activating or deactivating each pixel.

Each pixel comprises several sub-pixels.

Each sub-pixel is configured to emit a specific color, so that the color emitted by the pixel may be modified by controlling the sub-pixels to be activated or by modifying the electric current applied to each sub-pixel in order to modify the relative emission intensity of each sub-pixel.

Each sub-pixel itself contains at least one LED. In fact, a sub-pixel may contain a plurality of LEDs.

Each pixel typically comprises:
at least one sub-pixel formed by at least one LED able to directly generate, or to transmit through a suitable color converter, blue light,
at least one sub-pixel formed by at least one LED able to directly generate, or to transmit through a suitable color converter, green light,
at least one sub-pixel formed by at least one LED able to directly generate, or to transmit through a suitable color converter, red light.

More precisely, the LEDs have the form of a stack of semiconductor layers. The light is emitted when an electric current flows through the stack.

However, although certain technologies and certain materials used in the manufacture of LED allow a good emission efficiency over a specific part of the visible spectrum, for example in the blue range, the same technologies generally lead to much lower efficiencies when used to make a LED emitting over another part of the light spectrum.

This is why a suitable color converter (in other words a radiation converter) may be placed on the LED in order to convert the light emitted by the LED into light having a wavelength different from that of the light originally emitted by said LED.

Thus, sub-pixels may be obtained by placing radiation converters on specific areas of the LED, so that, by selectively supplying electric current to the area under each converter, the light emitted by the LED is converted into light having a specific color.

There are different embodiments of radiation converters.

Generally, a radiation converter is in the form of a matrix in which a set of particles made of the conversion material is incorporated. Preferably, these particles are quantum dots.

The quantum dots are three-dimensional semiconductor nanoparticles of crystalline structure, having quantum confinement properties in the three dimensions of space. They have different physical properties, namely magnetic, electrical and optical, depending on their dimensions and the materials of which they are made. The dimensions of the quantum dots are usually comprised between 1 and 100 nm.

The quantum dots have the very interesting property of being photoluminescent. This means that, when illuminated by a light source, they absorb photons from the light source and then re-emit light in response to this photoexcitation. While the absorption wavelength band (namely the illumination wavelength band in which a quantum dot absorbs photons) may be relatively wide, the emission wavelength band (namely the wavelength band in which the quantum dot re-emits light) is generally very narrow; for example with a width at half maximum of less than 50 nm. Moreover, the central wavelength of the emission band may be fine-tuned by optimizing the dimensions of the quantum dot.

This is why the quantum dots are nanoparticles of choice in the constitution of the radiation converters contained in the optoelectronic devices.

The matrix in which the quantum dots are incorporated is generally a photo- or heat-sensitive resin which is commonly used in the field of electronics to define patterns on a semiconductor surface, and this by solidifying and removing specific areas of said resin. The areas to be removed or to be solidified (in other words to be polymerized) are defined by insolation using a wavelength to which the resin is sensitive.

The quantum dots which are initially in the form of a powder are dispersed in a solvent, for example 2-methoxy-1-methylethyl acetate (hereinafter abbreviated to “PGMEA”). The solution thus obtained is then mixed with the photo- or heat-sensitive resin so that the quantum dots are incorporated therein as homogeneously as possible (namely in the absence of the formation of aggregates).

However, the quantum dots are very fragile materials which are sensitive to oxidation and in particular to external agents such as water, oxygen and free radicals resulting from polymerization reactions of the photo- or heat-sensitive resin. Moreover, the stability of the quantum dots may be low (in the range of a few hours) when they are subjected to a flux of heat and/or light, which is the case in the optoelectronic devices.

However, it is essential that the quantum dots maintain their optical properties over time (namely their very narrow emission wavelength band and their conversion efficiency) so that they retain all their interest in the constitution of the radiation converters.

It is currently known to encapsulate the sub-pixels so as to protect the quantum dots from the aforementioned external agents. The sub-pixels are encapsulated with a layer of metal oxide with thickness varying between 20 nm and 100 nm, deposited by an atomic layer deposition technique (commonly called “ALD”).

The ALD makes it possible to obtain a dense and reliable deposit which follows the topography of the surface of the sub-pixels and whose thickness may be controlled at the nanometric scale. Various oxides may be used as the material of the metal oxide layer, among which mention may be made of Al₂O₃, TiO₂, ZrO₂, ZnO and SiO₂, and mixtures thereof. The thickness of this deposit may be comprised between 20 nm and 500 nm, preferably between 50 nm and 100 nm. The ALD has several advantages compared to other methods allowing the coating of particles with one or several layers, such as for example the sol-gel method. The sol-gel method goes through a liquid phase, which is not the case of ALD. A disadvantage linked to the fact of passing through a liquid phase is that less pure layers are obtained, in particular when the core is initially surrounded by ligands: in fact, these ligands remain in solution and the liquid phase entails the risk that these residual ligands are encapsulated in the layer. On the contrary; with the ALD method, these ligands are vaporized and therefore disappear. Consequently, the ALD allows a better control of the thickness of the layers as well as a better control of the purity of the materials constituting the layers. The ALD also makes it possible to deposit a greater variety of layer materials than in the case of a sol-gel method, due to the greater versatility in the case of ALD.

However, this solution for encapsulating the sub-pixels is not totally satisfactory, because the quantum dots are not individually protected, and are thus always liable to be in contact with the aforementioned external agents which will degrade them, and in particular when the aforementioned agents are present in the photo- or heat-sensitive resin.

This is why we are looking for reliable means for protecting the quantum dots in an individualized manner and which are also effective for their homogeneous dispersion within the solvent, then the photo- or heat-sensitive resin.

### BRIEF SUMMARY

The disclosure overcomes these difficulties of protecting quantum dots for radiation converters and have developed new light-emitting and protected nanoparticles (in particular protected quantum dots), as well as their manufacturing method.

The present disclosure is described with specific reference to the quantum dots, without this limiting its scope. Indeed, the present disclosure may be applied to any light-emitting nanoparticle which needs to be protected against the oxidation and in particular the external agents chosen from water, oxygen and free radicals resulting from polymerization reactions of photo- or heat-sensitive resin.

The disclosure provides a light-emitting and protected nanoparticle which is composed of a light-emitting nanoparticle in the form of a light-emitting core optionally totally or partially coated with a layer of first ligands bonded to the surface of said core, said core, where appropriate said layer of first ligands, being coated with at least one oxidation protective layer, said light-emitting and protected nanoparticle is characterized in that it further comprises a layer formed of second ligands which are grafted to the surface of said oxidation protective layer.

The light-emitting core may be chosen from the quantum dots, metallic nanoparticles (for example gold, silver or nickel nanoparticles), metal oxide nanoparticles (for example zinc oxide nanoparticles), silicon nanoparticles, germanium nanoparticles, nanophosphors (for example YAG), rare earth nanoparticles and carbon dots.

Preferably, the light-emitting core is a quantum dot.

In this embodiment of the disclosure, the quantum dot may comprise at least one semiconductor nanocrystal chosen from group II-VI, group III-V or group IV-VI semiconductor nanocrystals, taken alone or as a mixture thereof.

The group II-VI semiconductor nanocrystal may be chosen from: CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe and HgSTe.

The group III-V semiconductor nanocrystal may be chosen from: GaN, GaP, GaAs, GaSb, AIN, AIP, AIS, AlAs, AlSb, InN, InP, InAs, InSb, InGaN, GaNP, GaNAs, GaPAs, AlNP, AlNAs, AlPAs and InAlPAs.

The group IV-VI semiconductor nanocrystal may be chosen from: SbTe, PbSe, GaSe, PbS, PbSe, PbTe, SnS, SnTe and PbSnTe.

In other words, the quantum dot may comprise at least one semiconductor nanocrystal chosen from CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, GaN, GaP, GaAs, GaSb, AIN, AIP, AIS, AlAs, AlSb, InN, InP, InAs, InSb, InGaN, GaNP, GaNAs, GaPAs, AINP, AlNAs, AlPAs, InAIPAs, SbTe, PbSe, GaSe, PbS, PbSe, PbTe, SnS, SnTe and PbSnTe.

In one embodiment of the disclosure, the core of the nanoparticle is totally or partially coated with a layer of first ligands which are bonded to the surface of said core. The first ligands are capable of interacting, weakly or strongly, with the core of the nanoparticle thanks to covalent, ionic or van der Waals bonds.

Preferably, said first ligands are compounds of the following chemical formula (I):

[Chem I]

R-{tilde under (X)}{tilde under (ₙ)} (I)

in which:
n may be equal to 1, 2 or 3,
X is a group capable of interacting with the light-emitting core through covalent, ionic or Van der Waals type interactions,
R is a non-hydrolyzable organic group.

Advantageously, R is a non-hydrolyzable alkyl chain comprising between 3 and 20 carbon atoms.

For example, if the light-emitting core is a quantum dot, X may be an amine, a phosphine, a carboxylic acid or a thiol.

In this embodiment of the disclosure in which the light-emitting core is a quantum dot, the first ligands which are bound to the surface of the core may be chosen from octadecylamine, dodecanthiol, trioctylphosphine, lipoic acid, trioctylphosphine oxide, oyelamine, 9-octadecenoic acid and oleic acid.

If the light-emitting core is a metallic nanoparticle, X may be an amine or a thiol.

If the light-emitting core is a silicon nanoparticle, X may be a silane.

Light-emitting nanoparticles, the light-emitting core of which is totally or partially coated with a layer of first ligands, are marketed in particular by the company Sigma-Aldrich. For example, it could be:
nanoparticles whose light-emitting core is CdSe/ZnS and is coated with a layer of first ligands bonded to its surface, which are octadecylamine:
nanoparticles whose light-emitting core is CdS/ZnS and is coated with a layer of first ligands bound to its surface, which are oleic acid.

The oxidation protective layer may be a metal oxide layer. Preferably, it comprises at least one oxide chosen from Al₂O₃, SiO₂, TiO₂, ZrO₂, ZnO, B₂O₃, Co₂O₃, Cr₂O₃, CuO, Fe₂O₃, Ga₂O₃, HfO₂, In₂O₃, MgO, Nb₂O₅, NiO, SnO₂, Ta₂O₅ and HfO₂, taken alone or as a mixture thereof.

Quite preferably, the oxide is chosen from: Al₂O₃, SiO₂, TiO₂, ZnO and ZrO₂.

The oxidation protective layer may also be a layer of metal nitride (for example BN, AlN, GaN, InN and Zr₃N₄, taken alone or as a mixture thereof) or of oxynitride (for example SiON).

The oxidation protective layer may thus be a layer of metal oxide, metal nitride or oxynitride, taken alone or as a mixture thereof.

Advantageously, for reasons of ease and control of the method for depositing the oxidation protective layer on the core or, where appropriate, the layer of first ligands, said layer is a layer of metal oxide. Indeed, the deposition of metal nitride or oxynitride requires a higher temperature and is less easy to implement than the deposition of metal oxide.

The thickness of the oxidation protective layer may be comprised between 1 nm and 400 nm, preferably between 1 nm and 100 nm, more preferably between 20 nm and 70 nm.

Preferably; the oxidation protective layer comprises a plurality of layers superimposed on each other.

The plurality of layers is advantageous, because if defects are present on some of the layers, the risk is low that they are located in the same places so as to create an access point for the external agents (water, oxygen and free radicals) to the core of the nanoparticle to be protected. In other words, with an oxidation protective layer breaking down into a plurality of layers, the fragile core of the nanoparticle is better protected from the aforementioned external agents.

The oxidation protective layer may comprise between 1 and 100 layers, preferably between 2 and 20 layers, more preferably between 6 and 10 layers, superimposed on each other.

The thickness of each layer may be comprised between 1 nm and 100 nm, preferably between 2 nm and 20 nm, more preferably between 3 nm and 10 nm.

If the oxidation protective layer comprises a plurality of layers of metal oxides superimposed on each other, the external layer (namely the layer furthest from the core of the nanoparticle) is preferably devoid of Al₂O₃ which is sensitive to water vapour.

In one embodiment of the disclosure, the oxidation protective layer may comprise the following two layers:
a 1st layer with a thickness comprised between 2 nm and 100 nm, preferably between 5 and 50 nm, comprising Al₂O₃,
a 2nd so-called “external” layer superimposed on the 1st layer and with a thickness comprised between 5 nm and 50 nm, comprising TiO₂, ZrO₂, SiO₂ or ZnO, taken alone or as a mixture thereof.

In another embodiment of the disclosure, the oxidation protective layer may comprise an alternation of the following two layers which are superimposed on each other:
a 1st layer with a thickness comprised between 1 nm and 10 nm, comprising Al₂O₃,
a 2nd layer superimposed on the 1st layer and with a thickness comprised between 1 nm and 10 nm, comprising TiO₂, ZrO₂, SiO₂ or ZnO, taken alone or as a mixture thereof,
the total thickness of the protective layer being comprised between 30 nm and 100 nm and the external layer (namely the layer furthest from the core of the nanoparticle) not being a 1st layer comprising Al₂O₃.

Preferred embodiments of oxidation protective layers comprising metal oxides are detailed below.

According to a 1st embodiment of the disclosure, the oxidation protective layer is a single layer with a thickness of 50 nm which comprises Al₂O₃, TiO₂, ZrO₂, SiO₂ or ZnO, taken alone or as a mixture thereof.

According to a 2nd embodiment of the disclosure, the oxidation protective layer comprises the following two layers:
a 1st layer with a thickness of 25 nm comprising Al₂O₃,
a 2nd so-called “external” layer superimposed on the 1st layer and with a thickness of 25 nm comprising TiO₂, ZrO₂, SiO₂ or ZnO, taken alone or as a mixture thereof.

According to a 3rd embodiment of the disclosure, the oxidation protective layer comprises the following two layers:
a 1st layer with a thickness of 40 nm comprising Al₂O₃,
a 2nd so-called “external” layer superimposed on the 1st layer and with a thickness of 10 nm comprising TiO₂, ZrO₂, SiO₂ or ZnO, taken alone or as a mixture thereof.

According to a 4th embodiment of the disclosure, the oxidation protective layer comprises an alternation of the following two layers which are superimposed on each other:
a 1st layer with a thickness of 5 nm comprising Al₂O₃,
a 2nd layer superimposed on the 1st layer and with a thickness of 5 nm comprising TiO₂, ZrO₂, SiO₂ or ZnO, taken alone or as a mixture thereof,
the total thickness of the protective layer being comprised between 30 nm and 100 nm and the external layer (namely the layer furthest from the core of the nanoparticle) not being a 1st layer comprising Al₂O₃.

The second ligands of the layer formed of second ligands which are grafted to the surface of the oxidation protective layer may advantageously be silanes, preferably silanes of the following chemical formula (II):

[Chem II]

RₙSiY₄₋ₙ (II)

in which:
n is equal to 1, 2 or 3,
Y is a hydrolyzable group, preferably an alkoxy, halide or amine group,
R is a non-hydrolyzable organic group.

Most preferably, the second ligands are silanes of the following chemical formula (III):

[Chem III]

{tilde under (R)}{tilde under (ₙ)}{tilde under (S)}{tilde under (i)}(OR′)₄₋ₙ (III)

in which:
n is equal to 1, 2 or 3,
R is a non-hydrolyzable organic group,
R′ is an aliphatic organic group.

Most preferably, R′ is chosen from the methyl, ethyl and isopropryl groups.

For example, the silanes may be chosen from n-propyltrimethoxysilane, allyltrimethoxysilane, n-propyltriethoxysilane, trimethoxy(7-octen-1-yl)silane, trimethoxy(octadecyl)silane, n-octyltrimethoxysilane, n-octyltriethoxysilane, methoxy(triethyleneoxy)propyltrimethoxysilane, 3-aminopropyltrimethoxysilane, phenyltrimethoxysilane, dimethoxy(methyl)octylsilane, 3-mercaptopropyltrimethoxysilane, 3-(methacryloyloxy)-propyltrimethoxysilane, 3-isocyanatopropyltriethoxysilane, 3-isocyanatopropyltrimethoxysilane, 2-[methoxy(polyethyleneoxy)6-9propyl]trimethoxysilane, 3-glycidoxypropyltrimethoxysilane, N-(3-acryloxy-2-hydroxypropyl)-3-aminopropyltriethoxysilane, bis[3-(triethoxysilyl)propyl]urea, 3-(trimethoxysilyl)propryl acrylate, 3-(trimethoxysilyl)propyl methacrylate and [3-(2,3-epoxypropoxy)-propyl]-trimethoxysilane.

The surface of the oxidation protective layer, which may be a layer of metal oxide, metal nitride, oxynitride or a mixture thereof, is very advantageous, since it is reactive and allows the attachment (in other words the grafting) of the second ligands to its surface.

For example, when the second ligands are silanes of chemical formula (II) or (III), the group Si—R of these second silane ligands is grafted to the surface of the oxidation protective layer. Indeed, hydroxyl groups are naturally present on the surface of the oxidation protective layer. In addition, by a surface activation process consisting in the exposure of said surface of the oxidation protective layer to ultraviolet radiation with a wavelength comprised between 185 nm and 254 nm which generate reactive area in-situ, new hydroxyl groups may be easily created.

Thus, in the case where the second ligands are silanes of chemical formula (II) or (III), when they are brought into contact with the hydroxylated surface of the oxidation protective layer, they condense with the hydroxyl groups present on the surface of the oxidation protective layer in such a way that the silicon of the groups Si—R binds covalently to the oxygen of said hydroxyl groups.

The surface of the oxidation protective layer is thus functionalized with the second ligands, preferably silanes.

Furthermore, the non-hydrolysable organic groups R of the second silane ligands will allow the dispersion of said light-emitting and protected nanoparticles within the solvent, then within the photo- or heat-sensitive resin without them forming aggregates.

The groups R of the second silane ligands are advantageously chosen according to the chemical affinity with the solvent and the photo- or heat-sensitive resin in which the light-emitting and protected nanoparticles according to the disclosure are dispersed.

The light-emitting and protected nanoparticles according to the disclosure have the advantage of including an oxidation protective layer which perfectly protects their sensitive core from the external agents (water, air and free radicals), said core not having to absolutely not be altered at the risk of reducing the optical properties of said nanoparticles.

In addition, thanks to the metal oxides, metal nitrides and oxynitrides or a mixture thereof, the oxidation protective layer constitutes an excellent means for grafting second ligands (preferably silanes as described above) whose non-hydrolyzable organic groups may easily be modulated, by choosing them appropriately by chemical affinity with the photo- and heat-sensitive resins and solvents in which it is desired to incorporate said nanoparticles, and this without said protected nanoparticles forming aggregates, which would also be prohibitive for their use in the constitution of radiation converters.

In other words, the protected nanoparticles according to the disclosure have a heart that is perfectly protected from the aforementioned external agents and may be easily incorporated in a solvent and a photo-or heat-sensitive resin without forming aggregates.

In the context of the present disclosure, the light-emitting and protected nanoparticles in which the light-emitting core is a quantum dot and the second ligands are silanes are particularly advantageous and original with respect to the state of the art of the light-emitting nanoparticles for the reasons that are detailed below.

The silanes ensure a homogeneous dispersion of these nanoparticles within the photo- or heat-sensitive resin.

The silanes are grafted around the quantum dots through the oxidation protective layer which may naturally include, due to its chemical composition, attachment sites (or in other words grafting sites such as than the aforementioned hydroxyl groups) of the second ligands or, as explained above, these attachment sites may be created by activating the surface of the oxidation protective layer.

In other words, thanks to the oxidation protective layer with which they are provided, the light-emitting and protected nanoparticles according to the disclosure have the advantage of overcoming the known problem of the state of the art according to which the surface of the quantum dots which are devoid of oxides does not allow the attachment of silanes. Now, as explained above, the silanes constitute a particularly suitable means for being able to disperse quantum dots within a photo- or heat-sensitive resin.

Thus, in addition to its function of protecting the light-emitting core which was mentioned above, the oxidation protective layer of the nanoparticles according to the disclosure also allows the grafting of silanes around the quantum dots and thus their homogeneous dispersion within a photo- or heat-sensitive resin.

Finally, the oxidation protective layer allows the grafting of a wide range of second ligands, preferably silanes, and therefore consequently the dispersion of the nanoparticles according to the disclosure in a wide range of photo- or heat-sensitive resins.

Indeed, the silanes are easily accessible and commercially available chemical compounds. Their grafting on a surface having oxides such as the surface of the oxidation protective layer is easy to implement. The surface of the oxidation protective layer may be readily functionalized with a variety of second ligands, preferably with a variety of silanes, which may be appropriately chosen such that they are chemically compatible with photo- or heat-sensitive resin (in particular radiation converter resins) in which it is desired to incorporate the nanoparticles according to the disclosure, the light-emitting core of which is preferably a quantum dot.

Thus, the nanoparticles according to the disclosure, the light-emitting core of which is a quantum dot and the second ligands of the silanes which may be chosen from a wide range of silanes, also have the advantage of flexibility in the choice of the photo- or heat-sensitive resin in which they are incorporated.

A subject of the disclosure is a dispersion of light-emitting and protected nanoparticles according to the disclosure as described above in an organic or inorganic non-aqueous solvent.

The solvent in which said nanoparticles according to the disclosure are dispersed may be an aliphatic or aromatic solvent. For example, the solvent is chosen from chloroform, toluene, hexane, PGMEA, ethyl acetate, acetonitrile and ethanol.

In said dispersion, the concentration of said emitting nanoparticles according to the disclosure may be comprised between 1 mg/mL and 900 mg/mL, preferably between 100 mg/mL and 500 mg/mL.

A subject of the disclosure is also a resin composition which comprises light-emitting and protected nanoparticles according to the disclosure as described above.

Preferably, the resin is a photo- or heat-sensitive resin. It may be chosen from vinyl ester, epoxy acrylate, polyimide and unsaturated polyester resins. It may for example be a resin of the SU-8 type (namely a resin composed of epoxy resin, propylene carbonate, triaryl-sulfonium initiator and an organic solvent chosen from cyclopentanone or gamma-butyrolactone, depending on the formulation).

For example, in the case where the second ligands are silanes of chemical formula (II) or (III), if the group R is:
an acrylate group, the nanoparticles according to the disclosure may be dispersed in a photosensitive acrylate resin;
an epoxy group, the nanoparticles according to the disclosure may be dispersed in an epoxy photosensitive resin;
an imide group, the nanoparticles according to the disclosure may be dispersed in a photosensitive polyimide resin;
an ester group, the nanoparticles according to the disclosure may be dispersed in a photosensitive polyester resin;
a propylacrylate group, the nanoparticles according to the disclosure may be dispersed in a solvent chosen from PGMEA or ethyl acetate;
a saturated or unsaturated aliphatic chain group (for example octyl or (7-octen-1-yl)), the nanoparticles according to the disclosure may be dispersed in a solvent chosen from toluene or chloroform.

The resin composition may comprise, in mass percentages expressed relative to the mass of said composition:
between 20% and 40% of said nanoparticles;
between 60% and 80% of resin.

A subject of the disclosure is also an optoelectronic device comprising a plurality of pixels which each comprise a plurality of sub-pixels, each sub-pixel being configured to emit a specific color and comprises at least one light emitter emitting a light radiation of a given color, said optoelectronic device comprises at least one radiation converter which is disposed close to the at least one light emitter and is characterized in that the radiation converter comprises the resin composition according to the disclosure which has been described above.

Preferably, the light emitter is a LED.

In the context of the present disclosure, the term “the radiation converter is disposed close to the at least one light emitter” means that the radiation converter is disposed on or around the light emitter, and this without necessarily a direct contact between the light emitter and the radiation converter. Indeed, the radiation converter may be an element attached to the optoelectronic device. There may be a transparent support layer (for example made of SiO₂) or a layer of glue which is interposed between the light emitter and the radiation converter. In other possible embodiments of the disclosure, an optical device for focusing or ensuring a directivity of the radiation may also be interposed between the light emitter and the radiation converter.

Preferably, the radiation converter is disposed on the light emitter. In other words, in this embodiment of the disclosure, the radiation converter is in contact with the light emitter.

The radiation converter may consist of a layer of the resin composition according to the disclosure. This layer may have a thickness comprised between 500 nm and 10 μm.

The layer of the resin composition may be applied to the light emitter (preferably a LED) by spin coating so as to obtain the radiation converter.

The disclosure also relates to the use of a resin composition according to the disclosure as described above as a radiation converter of an optoelectronic device.

The disclosure also relates to a method for manufacturing light-emitting and protected nanoparticles according to the disclosure as described above, which comprises at least the following steps:
a) light-emitting nanoparticles are provided in the form of light-emitting cores which are optionally totally or partially coated with a layer of first ligands which are bonded to the surface of said cores;
b) the cores, where appropriate the layer of first ligands of these cores, are coated with an oxidation protective layer by ALD, so as to obtain nanoparticles whose core is protected, where appropriate whose core totally or partially coated with a layer of first ligands is protected;
c) the nanoparticles obtained at the end of step b) are dispersed in a solution of second ligands so that the second ligands are grafted to the surface of the oxidation protective layer by forming a layer of second ligands on the surface of said oxidation protective layer.

The technical characteristics of the core, of the optional layer of first ligands totally or partially coating the core, as well as of the oxidation protective layer have been described above.

Preferably, the core of the light-emitting nanoparticles does not have a layer of first ligands which are bonded to its surface. This has the advantage in step b) of the method according to the disclosure, of facilitating the realization of the deposition of the oxidation protective layer and of improving its quality (namely a good homogeneity around the core and flawless). The oxidation protective layer thus ensures a better protection of the core of the nanoparticle.

In one embodiment of the disclosure, light-emitting nanoparticles may initially be provided in the form of light-emitting cores which are totally or partially coated with a layer of first ligands. This layer of first ligands may be totally or partially removed by an appropriate thermochemical treatment before implementing step b) of the method according to the disclosure.

In other words, if the light-emitting cores are totally or partially coated with a layer of first ligands bonded to the surface of said cores, the manufacturing method according to the disclosure may comprise an additional step which is carried out before step b) and which consists of a thermochemical treatment intended to remove all or part of said first ligands. This thermochemical treatment is perfectly within the reach of those skilled in the art.

By way of example, the thermochemical treatment may consist of one of the following treatments:

The 1st treatment consists in drying the light-emitting nanoparticles, then in bringing them into contact with ammonium sulphide in methanol. Then, washing in an organic medium (hexane/methanol extraction), followed by drying in an autoclave, makes it possible to obtain light-emitting nanoparticles whose first ligands have been totally or partially removed.

The 2nd treatment consists in drying the light-emitting nanoparticles, then subjecting them to ultraviolet radiation at a wavelength comprised between 120 nm and 250 nm. This allows the percolation of said nanoparticles and thus the removal of the first ligands totally or partially.

The 3rd treatment consists in bringing the light-emitting nanoparticles into contact with disulfur in N,N-dimethylformamide so that the first ligands are replaced by sulfur atoms and therefore totally or partially removed from said nanoparticles. This treatment is followed by slow drying in an autoclave.

Step b) implementing a deposition by ALD may be carried out in a reactor at a temperature comprised between room temperature and 400° C. The deposition by ALD may be thermal or plasma assisted. Advantageously, the deposition of step b) is carried out by plasma-assisted ALD in a fluidized bed reactor.

Before carrying out step c), the manufacturing method according to the disclosure may comprise an additional step consisting in exposing the surface of the oxidation protective layer to ultraviolet radiation with a wavelength comprised between 185 nm and 254 nm. As explained above, this process of surface activation generating reactive ozone in-situ, creates new hydroxyl groups on the surface of the oxidation protective layer on which will be able to bind, covalently, the second ligands of the solution of second ligands during step c).

During step c), the nanoparticles obtained at the end of step b) are dispersed in a solution of second ligands. The second ligands may be chosen from those which have been described above in the description of the light-emitting and protected nanoparticles according to the disclosure.

The solution of second ligands comprises at least one solvent which may be chosen from inorganic or organic non-aqueous solvents. It may for example be chloroform, toluene, hexane, ethanol, acetonitrile, ethyl acetate or PGMEA. The solvent is chemically compatible with the second ligands.

The mass percentage of the nanoparticles which are dispersed in the solution of second ligands relative to the mass of said solution of second ligands may be comprised between 10% and 70%.

The concentration of second ligands in said solution of second ligands may be comprised between 10 and 100000 times the concentration of the nanoparticles obtained at the end of step b) which are dispersed in said solution of second ligands.

The dispersion of the nanoparticles may be carried out at room temperature, preferably under an inert atmosphere and with stirring at a speed comprised between 200 and 2500 revolutions/minute.

In one embodiment of the disclosure, at the end of step c) of the manufacturing method, the solution of second ligands in which the light-emitting and protected nanoparticles are dispersed is mixed with a photo- or heat-sensitive resin, for example a photo- or heat-sensitive resin as described above.

In other embodiments of the disclosure, at the end of step c), the light-emitting and protected nanoparticles are extracted from the solution of second ligands by performing at least one step chosen from extraction, precipitation and centrifugation steps.

In one embodiment of the disclosure, the nanoparticles obtained at the end of step c) are successively subjected to an extraction, precipitation and centrifugation step.

The nanoparticles thus extracted may then be dispersed in a solvent, for example a solvent chosen from those described above so as to obtain a dispersion of said nanoparticles as described above. This dispersion may then be incorporated into a photo- or heat-sensitive resin, for example a photo- or heat-sensitive resin as described above.

The solvent of the solution of second ligands may be the same as that in which the light-emitting nanoparticles of step a) were dispersed.

In addition, as explained above, the second ligands of the solution of second ligands of step c) preferably have a chemical affinity:
on the one hand with the resin in which it is desired to disperse the light-emitting and protected nanoparticles according to the disclosure;
on the other hand with the solvent of the solution of second ligands.

In other words, the choice of the photo- or heat-sensitive resin in which it is desired to incorporate the light-emitting and protected nanoparticles according to the disclosure may direct the choice of the second ligands of the solution of second ligands. And these second ligands may for their part direct the choice of the solvent of the solution of second ligands.

In one embodiment of the disclosure, the manufacturing method may be carried out as follows:
a) light-emitting nanoparticles (preferably quantum dots) are provided in the form of light-emitting cores;
b) the light-emitting cores are coated by ALD at a temperature of 150° C. with a layer of SiO₂ with a thickness of 50 nm;
c) the nanoparticles obtained at the end of step b) are dispersed in a solution of PGMEA which contains 3-(trimethoxysilyl)propyl methacrylate (namely second ligands), the mass percentage of the nanoparticles with respect to the mass of said solution of second ligands is 40% and the concentration of second ligands is 10000 times greater than the concentration of the nanoparticles in said solution which is maintained for 12 hours under an inert atmosphere and with stirring at a speed of 1000 revolutions/minute.

At the end of step c), the nanoparticles are extracted in a hexane/methanol mixture with volume ratios comprised between 50/50 and 80/20. Then, the nanoparticles collected in methanol are precipitated using methanol or ethanol. The precipitate thus obtained is then centrifuged so as to recover the light-emitting and protected nanoparticles according to the disclosure in the solid state. These extraction/precipitation/centrifugation steps may be repeated until obtaining nanoparticles of sufficient purity.

### EXPERIMENTAL PART

Experiments have been carried out on oxidation protective layers corresponding to the 1st, 2nd, 3rd and 4th embodiments of the oxidation protective layer which have been described above.

These experiments consisted in determining the helium permeability of the oxidation protective layers so as to evaluate the barrier properties of said layers. The lower the helium permeability of the oxidation protective layer, the better the barrier effect of said layer or in other words the better its function of protecting the light-emitting core.

The experimental protocol was as follows:

Each tested oxidation protective layer was carried out by ALD on a polyimide support with a thickness of 125 μm so as to constitute a sample.

The samples thus obtained for each of the tested oxidation protective layers were inserted into a permeameter, namely a measuring device which combines a vacuum chamber with a mass spectrometer. This made it possible to measure the amount of helium diffused through each of these samples (or in other words the helium permeability of each of these samples).

In addition, the helium permeability of a so-called “reference” sample which consisted solely of the polyimide support (therefore devoid of any oxidation protective layer) was measured.

A decrease in helium permeability of 2 orders of magnitude was observed with these oxidation protective layers compared to the helium permeability of the reference sample.

This means that the oxidation protective layers as described above in the 1st, 2nd, 3rd and 4th embodiments of the oxidation protective layer are particularly suitable for protecting the light-emitting core of the nanoparticle according to the disclosure against the external agents (water, oxygen and free radicals resulting from photo- or heat-sensitive resin polymerization reactions).

In addition, it was found during these experiments that the helium permeability of the samples of the 2nd, 3rd and 4th embodiments (namely the multi-layer samples) was lower than that samples of the 1st embodiment (namely the single-layer samples). These experimental results thus confirmed that an oxidation protective layer decomposing into several layers had a better barrier effect than an oxidation protective layer in the form of a single layer. This oxidation protective layer in the form of a multi-layer is thus more effective in protecting the light-emitting core from the aforementioned external agents.

Finally, among all the tested samples, the lowest helium permeability was obtained with samples according to the 4th embodiment, namely samples whose oxidation protective layer comprised an alternation of two following layers which were superimposed on each other:
a 1st layer with a thickness of 5 nm comprising Al₂O₃,
a 2nd layer superimposed on the 1st layer and with a thickness of 5 nm comprising TiO₂, ZrO₂, SiO₂ or ZnO, taken alone or as a mixture thereof,
the total thickness of the protective layer being comprised between 30 nm and 100 nm and the external layer (namely the layer furthest from the core of the nanoparticle) not being a 1st layer of Al₂O₃.

These experimental results thus confirmed that the higher the number of layers of the oxidation protective layer, the better the barrier effect of this layer and therefore the better its ability to protect the emitting core from the aforementioned external agents.

### BRIEF DESCRIPTION OF THE DRAWINGS

The disclosure will be better understood with the aid of the detailed description which is given below with reference to the appended drawing showing, by way of non-limiting example, two implementations of the method for manufacturing light-emitting and protected nanoparticles according to the disclosure.

FIG. 1 is a schematic view of a 1st implementation of the method for manufacturing light-emitting and protected nanoparticles according to the disclosure, the core of which is not coated with a layer of first ligands.

FIG. 2 is a schematic view of a 2nd implementation of the method for manufacturing light-emitting and protected nanoparticles according to the disclosure, the core of which is coated with a layer of first ligands.

### DETAILED DESCRIPTION

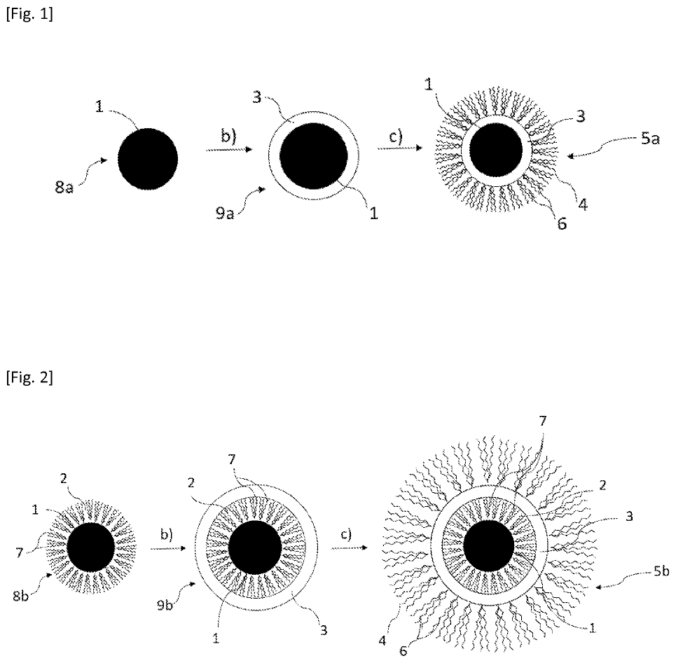

In FIG. 1 is represented a 1st embodiment of the manufacture of a light-emitting and protected nanoparticle 5a according to the disclosure. Initially, a light-emitting nanoparticle 8a was provided in the form of a core 1. The core 1 was a quantum dot composed of InP/ZnSe/ZnS.

During step b) of the manufacturing method according to the disclosure of said nanoparticle 5a, the core 1 was coated by ALD with an oxidation protective layer 3 composed of a 1st layer of AI₂O₃ with a thickness of 25 nm and of a 2nd layer of TiO₂ with a thickness of 25 nm which was superimposed on the 1st layer of AI₂O₃. A nanoparticle 9a was thus obtained, the core 1 of which was protected.

Next, the nanoparticle 9a was dispersed in step c) of the manufacturing method according to the disclosure in a solution of second ligands 6 containing 3-(trimethoxysilyl)propyl methacrylate (namely second ligands) and PGMEA as solvent, the concentration of the ligands being 10000 times greater than that of the nanoparticles 9a, and this at room temperature and under an inert atmosphere so as to obtain a light-emitting and protected nanoparticle 5a according to the disclosure. More specifically, during step c), the second ligands 6 are grafted to the surface of the oxidation protective layer 3 so as to form a layer 4 of second ligands 6.

In FIG. 2 is represented a 2nd embodiment of the manufacture of a light-emitting and protected nanoparticle 5b according to the disclosure which differs from the nanoparticle 5a only in that the core 1 is totally coated with a layer 2 of first ligands 7 consisting of 9-octadecenoic acid and which are bonded to the surface of said core 1. In other words, there was initially a light-emitting nanoparticle 8b whose core 1 was totally coated with a layer 2 of first ligands 7. Steps b) and c) of the manufacturing method according to the disclosure have been implemented to obtain the nanoparticle 5b in the same way as for the nanoparticle 5a. More specifically, at the end of step b), a light-emitting nanoparticle 9b was obtained, the core 1 of which coated with a layer 2 of first ligands 7, was protected by the oxidation protective layer 3.

1. A light-emitting and protected nanoparticle which is composed of a light-emitting nanoparticle in the form of a light-emitting core optionally totally or partially coated with a layer of first ligands bonded to the surface of said core, said core, where applicable said layer of first ligands, being coated with at least one oxidation protective layer, wherein said nanoparticle further comprises a layer formed of second ligands which are grafted to the surface of said oxidation protective layer.

2. The nanoparticle according to claim 1, wherein the core is chosen from quantum dots, metallic nanoparticles, metal oxide nanoparticles, silicon nanoparticles, germanium nanoparticles, nanophosphors, rare earth nanoparticles and carbon dots.

3. The nanoparticle according to claim 2, wherein the core is a quantum dot.

4. The nanoparticle according to claim 3, wherein the quantum dot comprises at least one semiconductor nanocrystal chosen from CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, GaN, GaP, GaAs, GaSb, AIN, AIP, AIS, AlAs, AlSb, InN, InP, InAs, InSb, InGaN, GaNP, GaNAs, GaPAs, AINP, AINAs, AlPAs, InAIPAs, SbTe, PbSe, GaSe, PbS, PbSe, PbTe, SnS, SnTe and PbSnTe.

5. The nanoparticle according to claim 1, wherein the core is totally or partially coated with a layer of first ligands which are bound to the surface of said core and in that said first ligands are compounds of the following chemical formula:
[Chem I]
R-{tilde under (X)}{tilde under (ₙ)} (I)
in which:
n may be equal to 1, 2 or 3,
X is a group capable of interacting with the light-emitting core through covalent, ionic or Van der Waals type interactions,
R is a non-hydrolyzable organic group.

6. The nanoparticle according to claim 5, wherein the core is a quantum dot and in that the first ligands which are bound to the surface of said core are chosen from octadecylamine, dodecanthiol, trioctylphosphine, lipoic acid, trioctylphosphine oxide, oyelamine, 9-octadecenoic acid and oleic acid.

7. The nanoparticle according to claim 1, wherein the thickness of the oxidation protective layer is comprised between 1 nm and 400 nm.

8. The nanoparticle according to claim 1, wherein the oxidation protective layer comprises a plurality of layers superimposed on each other.

9. The nanoparticle according to claim 1, wherein the oxidation protective layer is a layer of metal oxide, of metal nitride or of oxynitride, taken alone or as a mixture thereof.

10. The nanoparticle according to claim 9, wherein the oxidation protective layer comprises at least one metal oxide chosen from Al₂O₃, SiO₂, TiO₂, ZrO₂, ZnO, B₂O₃, Co₂O₃, Cr₂O₃, CuO, Fe₂O₃, Ga₂O₃, HfO₂, In₂O₃, MgO, Nb₂O₅, NiO, SnO₂, Ta₂O₅ et HfO₂, taken alone or as a mixture thereof.

11. The nanoparticle according to claim 10, wherein the oxidation protective layer comprises the following two layers:
a 1st layer with a thickness comprised between 2 nm and 100 nm comprising Al₂O₃,
a 2nd so-called “external” layer superimposed on the 1st layer and with thickness comprised between 5 nm and 50 nm, comprising TiO₂, ZrO₂, SiO₂ or ZnO, taken alone or as a mixture thereof.

12. The nanoparticle according to claim 10, wherein the oxidation protective layer comprises an alternation of the following two layers which are superimposed on each other:
a 1st layer with a thickness comprised between 1 nm and 10 nm, comprising Al₂O₃,
a 2nd layer superimposed on the 1st layer and with a thickness comprised between 1 nm and 10 nm, comprising TiO₂, ZrO₂, SiO₂ or ZnO, taken alone or as a mixture thereof,
the total thickness of the protective layer being comprised between 30 and 100 nm and the external layer (namely the layer furthest from the core of the nanoparticle) not being a 1st layer comprising Al₂O₃.

13. The nanoparticle according to claim 1, wherein the second ligands of the layer formed of second ligands which are grafted to the surface of the oxidation protective layer are silanes of the following chemical formula:
[Chem II]
RₙSiY₄₋ₙ (II)
in which:
n is equal to 1, 2 or 3,
Y is a hydrolyzable group, an alkoxy, halide or amine group,
R is a non-hydrolyzable organic group.

14. The nanoparticle according to claim 13, wherein said second ligands are silanes of the following chemical formula (III):
[Chem III]
{tilde under (R)}{tilde under (ₙ)}{tilde under (S)}{tilde under (i)}(OR′)₄₋ₙ (III)
in which:
n is equal to 1, 2 or 3,
R is a non-hydrolyzable organic group,
R′ is an aliphatic organic group.

15. A Dispersion of light-emitting and protected nanoparticles according to claim 1 in an organic or inorganic non-aqueous solvent.

16. The dispersion according to claim 15, wherein the solvent is chosen from chloroform, toluene, hexane, 2-methoxy-1-methylethyl acetate (abbreviated PGMEA), ethyl acetate, acetonitrile and ethanol.

17. The dispersion according to claim 15, wherein the concentration of said nanoparticles in said dispersion is comprised between 1 mg/mL and 900 mg/mL.

18. A resin composition, wherein it comprises light-emitting and protected nanoparticles according to claim 1.

19. The resin composition according to claim 18, wherein the resin is a photo- or heat-sensitive resin chosen from vinyl ester, epoxy acrylate, polyimide and unsaturated polyester resins.

20. The resin composition according to claim 18, wherein it comprises, in mass percentages expressed with respect to the mass of said composition:
between 20% and 40% of said nanoparticles;
between 60% and 80% of resin.

21. An optoelectronic device comprising a plurality of pixels which each comprise a plurality of sub-pixels, each sub-pixel being configured to emit a specific color and comprising at least one light emitter emitting a light radiation of a given color, said optoelectronic device comprises at least one radiation converter which is disposed close to the at least one light emitter, wherein the radiation converter comprises the resin composition according to claim 18.

22. The optoelectronic device according to claim 21, wherein the light emitter is a light-emitting diode.

23. A method for manufacturing light-emitting and protected nanoparticles according to claim 1, wherein it comprises at least the following steps:
a) light-emitting nanoparticles are provided in the form of light-emitting cores which are optionally totally or partially coated with a layer of first ligands which are bonded to the surface of said cores;
b) the cores, where appropriate the layer of first ligands of these cores, are coated with an oxidation protective layer by atomic layer deposition (commonly called “ALD”) so as to obtain nanoparticles whose core is protected, where appropriate whose core totally or partially coated with a layer of first ligands is protected;
c) the nanoparticles obtained at the end of step b) are dispersed in a solution of second ligands so that the second ligands are grafted to the surface of the oxidation protective layer by forming a layer of second ligands on the surface of said oxidation protective layer.

24. The manufacturing method according to claim 23, wherein the light-emitting cores are totally or partially coated with a layer of first ligands bonded to the surface of said cores and in that said manufacturing method comprises an additional step which is carried out before step b) and which consists of a thermochemical treatment intended to remove all or part of said first ligands.

25. The manufacturing method according to claim 23, wherein, before carrying out step c), said manufacturing method comprises an additional step consisting in exposing the surface of the oxidation protective layer to ultraviolet radiation with a wavelength comprised between 185 nm and 254 nm.

26. The resin composition according to claim 18 configured as a radiation converter of an optoelectronic device.
